(19) United States
(12) Patent Application Publication
(10) Pub. No.: US 2025/0151486 A1
(43) Pub. Date: May 8, 2025

(54) SEMICONDUCTOR STRUCTURE AND PREPARATION METHOD THEREOF

(71) Applicant: Enkris Semiconductor, Inc., Suzhou (CN)

(72) Inventors: Liyang ZHANG, Suzhou (CN); Kai CHENG, Suzhou (CN)

(21) Appl. No.: 18/795,612

(22) Filed: Aug. 6, 2024

(30) Foreign Application Priority Data
Nov. 6, 2023 (CN) 202311462351.X

(51) Int. Cl. H01L 33/60

(52) U.S. Cl. CPC H10H 20/856; H10H 20/0363; H10H 20/872

(57) ABSTRACT

Provided are a semiconductor structure and a preparation method thereof. The semiconductor structure includes a substrate, a buffer layer located on the substrate and a light-emitting structure located on a side of the buffer layer away from the substrate. The buffer layer includes a first region and a second region surrounding the first region. The semiconductor structure further includes a photoresist structure. The photoresist structure is formed by selectively etching the second region of the buffer layer, and the photoresist structure is configured to suppress lateral propagation of light emitted by the light-emitting structure. The light-emitting structure includes a light-emitting unit, and the light-emitting unit is disposed corresponding to the first region.

This application claims priority to Chinese Patent Application No. 202311462351X filed Nov. 6, 2023, the disclosure of which is incorporated herein by reference in its entirety.

### TECHNICAL FIELD

The present disclosure relates to the field of semiconductor technologies and, in particular, to a semiconductor structure and a preparation method thereof.

### BACKGROUND

Electrical power or electricity is usually transmitted through wires (such as copper wires). However, such wires may be heavy, bulky and expensive, and the transmitted power may be subject to electromagnetic interference. Some of these limitations can be overcome by transmitting power over optical fibers.

Gallium nitride (GaN)-based optoelectronic and electronic devices have enormous commercial importance. The best developed among these devices include light-emitting diodes (LEDs) and laser diodes, and GaN-based power diodes and transistors are becoming increasingly important. De Santi and the coauthor describe an application in [Materials 11,153 (2018)] where a laser diode is used for converting electrical power into optical power, which is coupled to an optic fiber and transmitted to a remote location, and then a photodiode is used for converting the optical power back into electrical energy.

When the LED is coupled to the optic fiber, the size of the LED chip usually needs to match the diameter of the optic fiber. Since the modulation speed of the LED is inversely proportional to the size of the LED, to improve the modulation speed, the size of the LED needs to be reduced. However, the size-reduced LED may cause problems such as optical crosstalk during coupling to the optic fiber.

### SUMMARY

The present disclosure provides a semiconductor structure and a preparation method thereof to avoid lateral propagation of light and improve the light output efficiency.

According to an aspect of the present disclosure, a semiconductor structure is provided.

The semiconductor includes a substrate, a buffer layer located on the substrate and a light-emitting structure located on a side of the buffer away from the substrate.

The buffer layer includes a first region and a second region surrounding the first region.

The semiconductor structure further includes a photoresist structure, where the photoresist structure is formed by selectively etching the second region of the buffer layer, and the photoresist structure is configured to suppress lateral propagation of light emitted by the light-emitting structure.

The light-emitting structure includes a light-emitting unit, and the light-emitting unit is disposed corresponding to the first region.

The buffer layer includes multiple first regions, and the second region surrounds all of the multiple first regions.

The light-emitting structure includes multiple light-emitting units, and the multiple light-emitting units are disposed corresponding to the multiple first regions one to one.

The photoresist structure includes a first photonic crystal structure, the first photonic crystal structure includes multiple small holes penetrating the buffer layer, and the multiple small holes cover the second region and are arranged at intervals.

Alternatively, the photoresist structure includes multiple annular grooves penetrating the buffer layer, and the multiple annular grooves are disposed at the same center and around the first region at intervals.

The semiconductor structure further includes a light-output structure, where the light-output structure is formed by selectively etching the first region of the buffer layer, and the light-output structure is configured to improve light output efficiency of the light-emitting unit.

The light-output structure includes multiple nano patterns located on a side of the buffer layer away from the light-emitting unit, and the multiple nano patterns are arranged in a regular or irregular manner on the side of the buffer layer away from the light-emitting unit.

The substrate includes a groove, the groove penetrates the substrate, and a vertical projection of the groove on the buffer layer corresponds to the first region and the second region.

The maximum size of a vertical projection of the light-emitting unit on the buffer layer is less than or equal to the size of the first region of the buffer layer corresponding to the light-emitting unit.

The light-emitting unit includes a first semiconductor layer, a light-emitting layer and a second semiconductor layer which are sequentially laminated, and the first semiconductor layer is located on a surface of the side of the buffer layer away from the substrate.

The light-emitting unit further includes a metal reflecting layer, and the metal reflecting layer is located on a side of the second semiconductor layer away from the light-emitting layer.

The semiconductor structure further includes a passivation layer.

The passivation layer is located on the side of the buffer layer away from the substrate, and the passivation layer covers a region of the buffer layer where no light-emitting unit is disposed and covers a side of the light-emitting unit away from the buffer layer.

A first through hole and a second through hole which expose the first semiconductor layer and the second semiconductor layer respectively are provided on a side of the passivation layer away from the substrate.

The semiconductor structure further includes a first electrode and a second electrode which are located within the first through hole and the second through hole respectively; the first electrode is electrically connected to the first semiconductor layer, and the second electrode is electrically connected to the second semiconductor layer through the metal reflecting layer.

The semiconductor structure further includes a drive base plate, the drive base plate is bonded to the side of the passivation layer away from the substrate, and the drive base plate provides an electrical signal for each of the light-emitting unit through the first electrode and the second electrode.

The semiconductor structure further includes an optical fiber.

The optical fiber is coupled to the groove of the substrate.

According to another aspect of the present disclosure, a preparation method of a semiconductor structure is provided. The method includes steps described below.

A substrate is provided.

A buffer layer is formed on a side of the substrate, where the buffer layer includes a first region and a second region surrounding the first region.

A light-emitting structure is formed on a side of the buffer layer away from the substrate; the light-emitting structure is patterned to form a light-emitting unit, where the light-emitting unit is disposed corresponding to the first region.

The second region of the buffer layer is selectively etched to prepare a photoresist structure, where the photoresist structure is configured to suppress lateral propagation of light emitted by the light-emitting structure.

The step in which the second region of the buffer layer is selectively etched to prepare the photoresist structure includes steps described below.

A side of the substrate away from the buffer layer is etched to form a groove that penetrates the substrate, where a vertical projection of the groove on the buffer layer corresponds to the first region and the second region.

The second region of the buffer layer is selectively etched to form the photoresist structure.

The photoresist structure includes a first photonic crystal structure, the first photonic crystal structure includes multiple small holes penetrating the buffer layer, and the multiple small holes cover the second region and are arranged at intervals.

Alternatively, the photoresist structure includes multiple annular grooves penetrating the buffer layer, and the multiple annular grooves are disposed at the same center and around the first region at intervals.

The buffer layer includes multiple first regions, and the second region surrounds all of the first regions. The step in which the light-emitting structure is patterned to form the light-emitting unit includes the step described below.

The light-emitting structure is patterned to form multiple light-emitting units, and the multiple light-emitting units correspond to the multiple first regions one to one.

The step in which the light-emitting structure is formed on the side of the buffer layer away from the substrate includes sequentially forming a first semiconductor layer, a light-emitting layer and a second semiconductor layer on the side of the buffer layer away from the substrate. After the light-emitting structure is patterned to form the light-emitting unit, the step described below is further included.

A metal reflecting layer is formed on a side of the second semiconductor layer away from the light-emitting layer.

After the metal reflecting layer is formed on the side of the second semiconductor layer away from the light-emitting layer, steps described below are further included.

A passivation layer is formed on the side of the buffer layer away from the substrate, where the passivation layer covers a region of the buffer layer where no light-emitting unit is disposed and covers a side of the light-emitting unit away from the buffer layer; a first through hole and a second through hole are formed on a side of the passivation layer away from the substrate to expose the first semiconductor layer and the metal reflecting layer respectively.

A first electrode is formed in the first through hole, and a second electrode is formed in the second through hole, where the first electrode is electrically connected to the first semiconductor layer, and the second electrode is electrically connected to the second semiconductor layer through the metal reflecting layer.

A drive base plate is provided, and the drive base plate is bonded to the side of the passivation layer away from the substrate, where the drive base plate provides an electrical signal for each light-emitting unit through the first electrode and the second electrode.

After the second region of the buffer layer is selectively etched to form the photoresist structure, the step described below is further included.

An optical fiber is provided, and the optical fiber is coupled to the groove of the substrate.

The first region of the buffer layer is selectively etched to prepare a light-output structure while the second region of the buffer layer is selectively etched to prepare the photoresist structure, where the light-output structure is configured to improve light output efficiency of the light-emitting unit.

The step in which the first region of the buffer layer is selectively etched to prepare the light-output structure includes the step described below.

Multiple nano patterns are formed on a side of the buffer layer away from the light-emitting unit, where the multiple nano patterns are arranged in a regular or irregular manner on the side of the buffer layer away from the light-emitting unit.

The semiconductor structure provided in the embodiment of the present disclosure includes a substrate, a buffer layer located on the substrate and a light-emitting structure located on a side of the buffer away from the substrate. The buffer layer includes a first region and a second region surrounding the first region. The semiconductor structure further includes a photoresist structure, where the photoresist structure is formed by selectively etching the second region of the buffer layer, and the photoresist structure is configured to suppress lateral propagation of light emitted by the light-emitting structure. The light-emitting structure includes a light-emitting unit, and the light-emitting unit is disposed corresponding to the first region. The photoresist structure has relatively high reflectivity in a direction perpendicular to a surface of the buffer layer, which can effectively suppress lateral propagation of light emitted by the light-emitting structure through the second region, reducing light loss and avoiding signal crosstalk. The light-emitting unit is disposed corresponding to the first region, so that the light emitted by the light-emitting structure is only guided out through a light output surface of the first region of the buffer layer, which can improve the light output efficiency.

It is to be understood that the content described in this part is neither intended to identify key or important features of embodiments of the present disclosure nor intended to limit the scope of the present disclosure. Other features of the present disclosure are apparent from the description provided hereinafter.

### BRIEF DESCRIPTION OF DRAWINGS

To illustrate technical solutions of embodiments of the present disclosure more clearly, drawings used in description of embodiments of the present disclosure are described hereinafter. Apparently, these drawings illustrate merely part of embodiments of the present disclosure. Those of ordinary skill in the art may obtain other drawings based on these drawings on the premise that no creative work is done.

FIG. 1 is a structural diagram of a semiconductor structure according to embodiment one of the present disclosure;

FIG. 2 is a structural diagram of another semiconductor structure according to embodiment one of the present disclosure;

FIG. 3A is a top view of a semiconductor structure according to embodiment one of the present disclosure;

FIG. 3B is a top view of another semiconductor structure according to embodiment one of the present disclosure;

FIG. 4 is a structural diagram of another semiconductor structure according to embodiment one of the present disclosure;

FIG. 5 is a flowchart of a preparation method of a semiconductor structure according to embodiment two of the present disclosure;

FIG. 6 is a structural diagram of a semiconductor structure according to embodiment two of the present disclosure;

FIG. 7 is a structural diagram of another semiconductor structure according to embodiment two of the present disclosure;

FIG. 8 is a structural diagram of another semiconductor structure according to embodiment two of the present disclosure;

FIG. 9 is a structural diagram of another semiconductor structure according to embodiment two of the present disclosure;

FIG. 10 is a flowchart of another preparation method of a semiconductor structure according to embodiment two of the present disclosure;

FIG. 11 is a structural diagram of another semiconductor structure according to embodiment two of the present disclosure;

FIG. 12 is a structural diagram of another semiconductor structure according to embodiment two of the present disclosure;

FIG. 13 is a structural diagram of another semiconductor structure according to embodiment two of the present disclosure;

FIG. 14 is a structural diagram of another semiconductor structure according to embodiment two of the present disclosure;

FIG. 15 is a structural diagram of another semiconductor structure according to embodiment two of the present disclosure; and

FIG. 16 is a structural diagram of another semiconductor structure according to embodiment two of the present disclosure.

### DETAILED DESCRIPTION

For a better understanding of the solutions of the present disclosure by those skilled in the art, the technical solutions in embodiments of the present disclosure are described clearly and completely below in conjunction with the drawings in embodiments of the present disclosure. Apparently, the embodiments described below are merely part, not all, of embodiments of the present disclosure. Based on embodiments of the present disclosure, all other embodiments obtained by those of ordinary skill in the art on the premise that no creative work is done are within the scope of the present disclosure.

It is to be noted that the terms “first”, “second” and the like in the description, claims and drawings of the present disclosure are used for distinguishing between similar objects and are not necessarily used for describing a particular order or sequence. It is to be understood that the data used in this manner is interchangeable in appropriate cases so that embodiments of the present disclosure described herein may also be implemented in a sequence not illustrated or described herein. Additionally, terms “including” and “having” as well as any variations thereof are intended to encompass a non-exclusive inclusion. For example, a process, method, system, product or device that includes a series of steps or units not only includes the expressly listed steps or units but may also include other steps or units that are not expressly listed or are inherent to such a process, method, product or device.

### Embodiment One

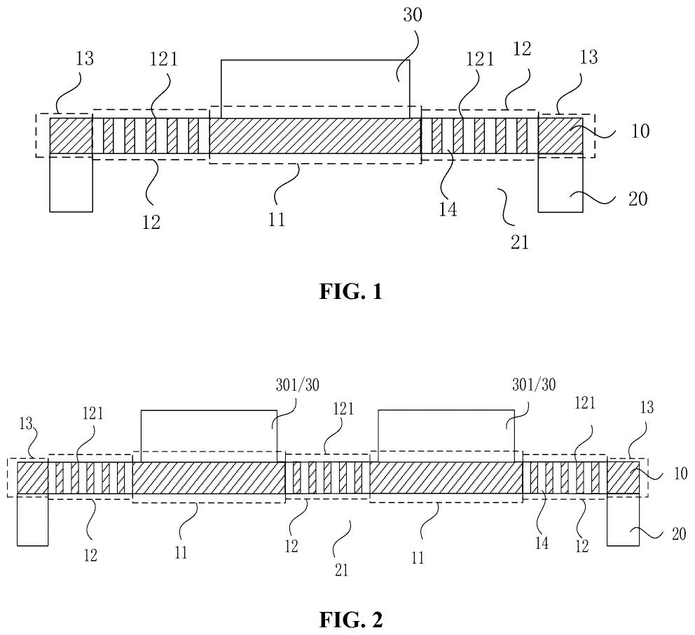

The embodiment of the present disclosure provides a semi-conductor structure. FIG. 1 is a structural diagram of a semiconductor structure according to embodiment one of the present disclosure.

Referring to FIG. 1, the semiconductor structure includes a substrate 20, a buffer layer 10 located on the substrate 20 and a light-emitting structure 30 located on a side of the buffer layer 10 away from the substrate 20. The buffer layer 10 includes a second region 12, a third region 13 and a first region 11. The second region 12 surrounds the first region 11, and the third region 13 surrounds the second region 12. The semiconductor structure further includes a photoresist structure 121. The photoresist structure 121 is formed by selectively etching the second region of the buffer layer 10, and the photoresist structure 121 is configured to suppress lateral propagation of light emitted by the light-emitting structure 30. The light-emitting structure 30 includes a light-emitting unit 301, and the light-emitting unit 301 is disposed corresponding to the first region 11.

The photoresist structure 121 is formed in the second region 12 of the buffer layer 10. The photoresist structure 121 is a structure in which the material of the buffer layer 10 is alternately arranged with the air. The alternation of the buffer layer 10 and the air leads to a relatively high refractive index, so that the photoresist structure 121 has relatively high reflectivity in a direction perpendicular to a surface of the buffer layer, which can effectively suppress lateral propagation of light emitted by the light-emitting structure 30 through the second region 12, avoiding light crosstalk. Therefore, the light-emitting unit 301 is disposed corresponding to the first region 11, so that the light emitted by the light-emitting structure 30 is only guided out through the first region 11 of the buffer layer 10, which can improve the light output efficiency.

The material of the substrate 20 is any one of substrate materials such as Si, SiC, Al₂O₃, AlN or GaN or the substrate 20 is a Qromis Substrate Technology (QST) substrate. The material of the buffer layer 10 is one of III nitride materials. In the embodiment, the material of the buffer layer 10 is the AlGaN material. The material of the light-emitting structure 30 is one of III nitride materials. In the embodiment, the material of the light-emitting structure 30 is the GaN-based material.

FIG. 2 is a structural diagram of another semiconductor structure according to embodiment one of the present disclosure. Referring to FIG. 2, the buffer layer 10 includes multiple first regions 11, the second region 12 surrounds the multiple first regions 11, and the third region 13 surrounds the second region 12. The light-emitting structure 30 includes multiple light-emitting units 301, the multiple light-emitting units 301 are disposed corresponding to the multiple first regions 11 one to one, and each light-emitting unit 301 is disposed in a first region 11 corresponding to the each light-emitting unit 301, that is, an orthographic projection of each light-emitting unit 301 on the buffer layer 10 is located in a first region 11.

Each light-emitting unit 301 is disposed in the first region 11 corresponding to the each light-emitting unit 301, ensuring that the light emitted by each light-emitting unit 301 only comes from a light output surface of the first region 11 corresponding to the each light-emitting unit 301, and thus avoiding optical signal crosstalk between multiple light-emitting units 301.

In an embodiment, the photoresist structure 121 includes a first photonic crystal structure, the first photonic crystal structure includes multiple small holes 15 penetrating the buffer layer 10, and the multiple small holes 15 cover the second region 12 and are arranged at intervals; or in other embodiments, the photoresist structure 121 may further include multiple annular grooves 14 penetrating the buffer layer 10, and the multiple annular grooves 14 are disposed at the same center and around the first region 11 at intervals.

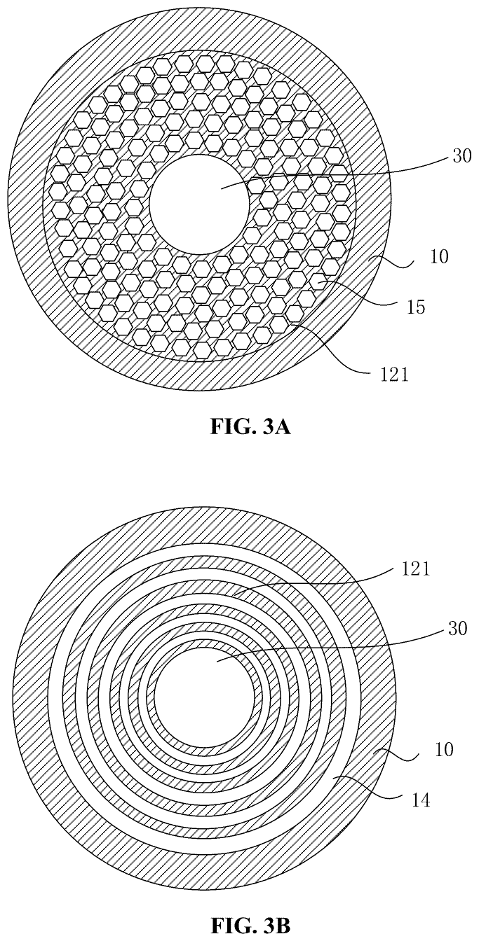

Referring to FIG. 3A, FIG. 3A is a top view of a semiconductor structure according to embodiment one of the present disclosure. The second region 12 of the buffer layer 10 forms the photoresist structure 121. The photoresist structure 121 includes a first photonic crystal structure, the first photonic crystal structure includes multiple small holes 15 penetrating the buffer layer 10, and the multiple small holes 15 cover the second region 12 and are arranged at intervals. In the second region 12, an effective refractive index between the small holes 15 and the material of the buffer layer 10 is relatively high, the small holes 15 penetrate the buffer layer 10 in a direction perpendicular to the buffer layer 10, and the multiple small holes 15 are arranged at intervals in a direction parallel to the buffer layer 10. Therefore, in the direction parallel to the buffer layer 10, the first photonic crystal structure, that is, the photoresist structure 121 has a relatively high effective refractive index in the direction parallel to the buffer layer 10, effectively suppressing the lateral guided propagation of light emitted by the light-emitting unit 301 through the second region 12, and thus effectively avoiding light crosstalk. In an optional embodiment, the diameter of the small hole 15 is less than 100 nm. In a direction pointing from the first region 11 to the second region 12, the arrangement density of the small holes 15 in the photoresist structure 121 remains unchanged, gradually decreases or increases so that the photoresist effect is further improved.

In other embodiments, referring to FIG. 3B, FIG. 3B is a top view of another semiconductor structure according to embodiment one of the present disclosure. The photoresist structure 121 includes multiple annular grooves 14 penetrating the buffer layer 10, and the multiple annular grooves 14 are disposed at the same center and around the first region 11 at intervals. Similarly, in the second region 12, an effective refractive index between the annular grooves 14 and the material of the buffer layer 10 is relatively high, the annular grooves 14 penetrate the buffer layer 10 in the direction perpendicular to the buffer layer 10, and the multiple annular grooves 14 are arranged at intervals around each other in the direction parallel to the buffer layer 10. Therefore, in the direction parallel to the buffer layer 10, the photoresist structure 121 has a relatively high effective refractive index in the direction parallel to the buffer layer 10, effectively suppressing the lateral guided propagation of light emitted by the light-emitting unit 301 through the second region 12, and thus effectively avoiding light crosstalk and reducing light loss. In an optional embodiment, the width of a section of the annular groove 14 is less than 100 nm, and the interval between multiple annular grooves 14 is less than 100 nm. The section is a surface perpendicular to a surface of the buffer layer 10. In the direction pointing from the first region 11 to the second region 12, the width of the section of the annular groove 14 in the photoresist structure 121 remains unchanged, gradually decreases or increases, and the section is a surface perpendicular to the surface of the buffer layer 10. The arrangement interval of the annular grooves 14 in the photoresist structure 121 remains unchanged, gradually decreases or increases so that the photoresist effect is further improved.

Referring to FIG. 16, the semiconductor structure further includes a light-output structure 111. The light-output structure 111 is formed by selectively etching the first region 11 of the buffer layer 10, and the light-output structure 111 is configured to improve the light output efficiency of the light-emitting unit 301.

The light-output structure 111 is located within the first region 11, and the light-output structure 111 includes multiple nano patterns located on a side of the buffer layer 10 away from the light-emitting unit 301. The multiple nano patterns partially penetrate the buffer layer 10, and the multiple nano patterns may be arranged in a regular or irregular manner on the side of the buffer layer 10 away from the light-emitting unit 301. The light-output structure 111 greatly improves the power and the light extraction efficiency of the light-emitting unit 301. The light-output structure 111 may be in the form of a wavy line, a serration or may be a nano-patterned structure formed by the combination of multiple nano protrusions and multiple nano grooves. The light-output structure 111 may include a second photonic crystal structure. The second photonic crystal structure includes multiple nano patterns arranged in a regular or irregular manner on the side of the buffer layer 10 away from the light-emitting unit 301.

Referring to FIG. 1, the substrate 20 includes a groove 21, the groove 21 penetrates the substrate 20, and a vertical projection of the groove 21 on the buffer layer 10 corresponds to the first region 11 and the second region 12.

The groove 21 may be formed by selectively etching the substrate 20 to form a beam modulation window.

The maximum size of a vertical projection of the light-emitting unit 301 on the buffer layer 10 is less than or equal to the size of the first region 11 of the buffer layer 10 corresponding to the light-emitting unit 301.

In an optional embodiment, the maximum size of the vertical projection of the light-emitting unit 301 on the buffer layer 10 is less than 10 m. The maximum size of the vertical projection of the light-emitting unit 301 on the buffer layer 10 is less than or equal to the size of the first region 11 of the buffer layer 10 corresponding to the light-emitting unit 301, ensuring that the light emitted by the light-emitting unit 301 is only guided out through the first region 11, which can suppress the lateral propagation of the light emitted by the light-emitting unit 301 and reduce light loss.

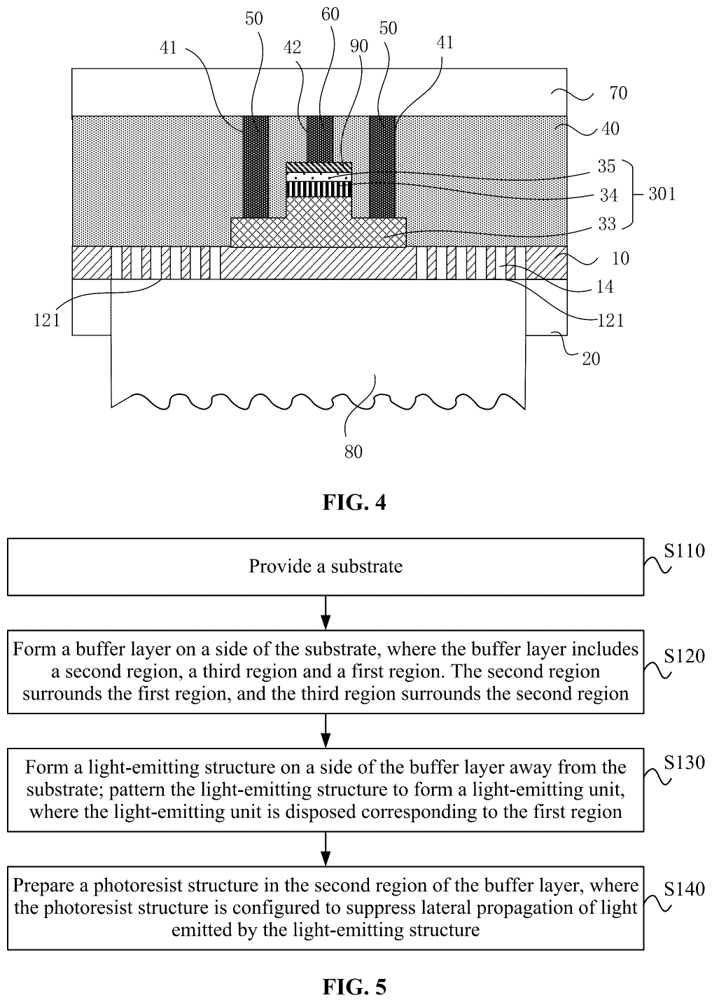

FIG. 4 is a structural diagram of another semiconductor structure according to embodiment one of the present disclosure. Referring to FIG. 1 to FIG. 4, the light-emitting unit 301 includes a first semiconductor layer 33, a light-emitting layer 34 and a second semiconductor layer 35 which are sequentially laminated, and the first semiconductor layer 33 is located on a surface of the side of the buffer layer 10 away from the substrate 20. The conduction type of the first semiconductor layer 33 is opposite to the conduction type of the second semiconductor layer 35. The first semiconductor layer 33 is an N-type semiconductor layer, and the second semiconductor layer is a P-type semiconductor layer; or the first semiconductor layer 33 is a P-type semiconductor layer, and the second semiconductor layer is an N-type semiconductor layer.

The light-emitting structure 30 is patterned, that is, the first semiconductor layer 33, the light-emitting layer 34 and the second semiconductor layer 35 are patterned to form the light-emitting unit 301, so that the size of a vertical projection of the light-emitting unit 301 on the buffer layer 10 and the size of a vertical projection of the second semiconductor layer 35 on the buffer layer 10 are less than or equal to the size of a vertical projection of the first semiconductor layer 33 on the buffer layer 10. The light-emitting unit 301 is disposed corresponding to the first region 11. In the process of patterning the first semiconductor layer 33, the light-emitting layer 34 and the second semi-conductor layer 35 to form the light-emitting unit 30, a surface that is not covered by the light-emitting layer 34 and the second semiconductor layer 35 may be formed on a side of the first semiconductor layer 33 away from the substrate 20 for the subsequent preparation of electrodes.

Referring to FIG. 4, the light-emitting unit 301 further includes a metal reflecting layer 90, and the metal reflecting layer 90 is located on a side of the second semiconductor layer 35 away from the light-emitting layer 34.

The metal reflecting layer 90 is configured to reflect the light emitted by the light-emitting unit 301, so that the output direction of the light is only the direction pointing from the light-emitting layer 34 to the buffer layer 10, improving the light output efficiency.

Referring to FIG. 4, the semiconductor structure further includes a passivation layer 40. The passivation layer 40 is located on the side of the buffer layer 10 away from the substrate 20, and the passivation layer 40 covers a region of the buffer layer 10 where no light-emitting unit 301 is disposed and covers a side of the light-emitting unit 301 away from the buffer layer 10. A surface of the passivation layer 40 away from the substrate 20 is formed as a flat surface for subsequent device processing.

The material of the passivation layer 40 may be dielectric materials such as silicon dioxide or silicon nitride, and the passivation layer 40 can play a role of isolation and insulation.

Referring to FIG. 4, the semiconductor structure further includes first electrodes 50 and a second electrode 60. The first electrodes 50 are electrically connected to the first semiconductor layer 33, and the second electrode 60 is electrically connected to the second semiconductor layer 35 through the metal reflecting layer 90.

The first electrodes 50 and/or the second electrode 60 may be in an annular shape or dot-contact. The passivation layer 40 has first through holes 41 and a second through hole 42 which penetrate the passivation layer 40. The first through holes 41 expose the first semiconductor layer 33, and the second through hole 42 exposes the metal reflecting layer 90. The first electrodes 50 cover the first through holes 41, and the second electrode 60 covers the second through hole 42. Due to the conductivity of the metal reflecting layer, the second electrode 60 can be electrically connected to the second semiconductor layer 35 through the metal reflecting layer 90. It is known that in the embodiment where no metal reflecting layer 90 is disposed, the second through hole 42 exposes the second semiconductor layer 35, and the second electrode 60 is connected to the second semiconductor layer 35. The first electrodes 50 and/or the second electrode 60 may be in an annular shape or dot-contact, that is, the first through holes 41 and/or the second through hole 42 are point-shaped through holes or annular through holes, that is, the sectional shape of the first through hole 41 and/or the sectional shape of the second through hole 42 parallel to a plane where the substrate 20 is located are circular or annular.

Referring to FIG. 4, the semiconductor structure further includes a drive base plate 70, the drive base plate 70 is bonded to the side of the passivation layer 40 away from the substrate 20, and the drive base plate 70 provides an electrical signal for each light-emitting unit 301 through the first electrodes 50 and the second electrode 60.

The drive base plate 70 may be a complementary metal oxide semiconductor (CMOS) drive base plate. The drive base plate 70 includes multiple drive units. Each drive unit drives a light-emitting unit 301 and provides an electrical signal for each light-emitting unit 301 through the first electrodes 50 and the second electrode 60.

Referring to FIG. 4, the semiconductor structure further includes an optical fiber 80, and the optical fiber 80 is coupled to the groove 21 of the substrate 20.

The optical fiber 80 is a single-mode fiber. In this semiconductor structure, the size of the light-emitting unit 301 is reduced, so that the modulation speed is greatly improved. Moreover, the first photonic crystal structure of the buffer layer 10 can avoid lateral propagation of light, avoid optical signal crosstalk, and ensure that light emitted by each light-emitting unit 301 is emitted from the corresponding first region, improving the light output efficiency.

The vertical projection of the light-emitting unit 301 on the buffer layer 10 may be in a circular shape, an elliptical shape or a polygonal shape.

The light-emitting unit 301 may be etched into various shapes through the etching process, and any one of the circular shape, the elliptical shape or the polygonal shape may be set according to requirements.

### Embodiment Two

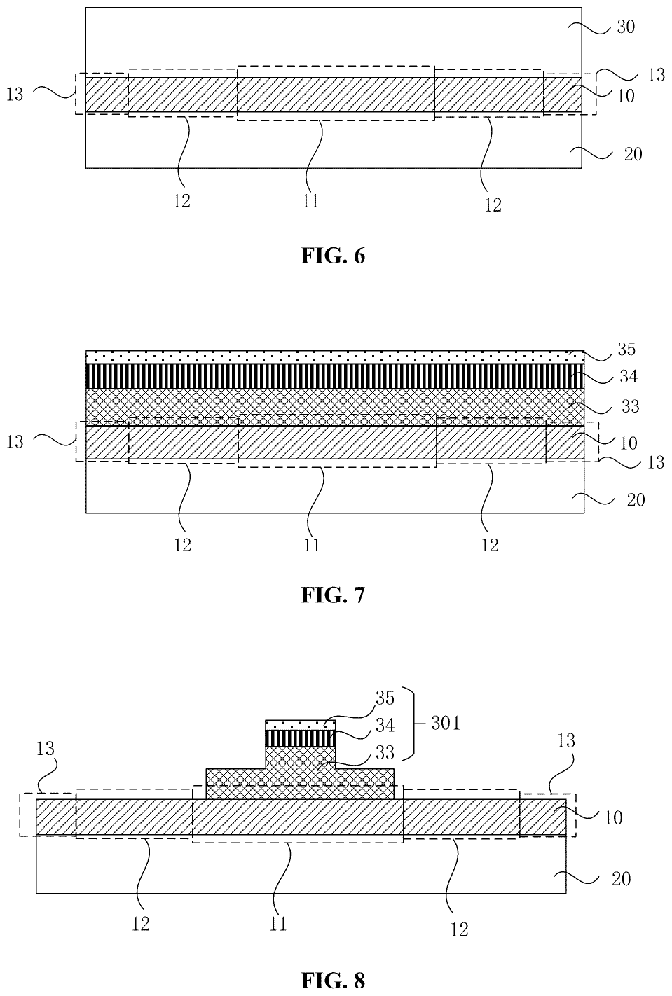

Embodiment two provides a preparation method of the semiconductor structure provided in embodiment one. FIG. 5 is a flowchart of a preparation method of a semiconductor structure according to embodiment two of the present disclosure, and FIG. 6 is a structural diagram of a semiconductor structure according to embodiment two of the present disclosure. Referring to FIG. 5 and FIG. 6, the preparation method includes steps described below.

In S110, a substrate 20 is provided.

The material of the substrate 20 is any one of substrate materials such as Si, SiC, Al₂O₃, AlN or GaN or the substrate 20 is a QST substrate.

In S120, a buffer layer 10 is formed on a side of the substrate 20, where the buffer layer 10 includes a second region 12, a third region 13 and a first region 11. The second region 12 surrounds the first region 11, and the third region 13 surrounds the second region 12.

The buffer layer 10 is epitaxially grown on the substrate 20. The material of the buffer layer 10 is one of III nitride materials. In the embodiment, the material of the buffer layer 10 is the AlGaN material.

In S130, a light-emitting structure 30 is formed on a side of the buffer layer 10 away from the substrate 20, where the material of the light-emitting structure 30 is one of III nitride materials, and in the embodiment, the material of the light-emitting structure 30 is the GaN-based material; the light-emitting structure 30 is patterned to form a light-emitting unit 301, where the light-emitting unit 301 is disposed corresponding to the first region 11.

The light-emitting structure 30 is epitaxially grown on the buffer layer 10. Structures in FIG. 1 and FIG. 2 are structures formed by patterning the light-emitting structure 30 in FIG. 6.

In S140, a photoresist structure 121 is prepared in the second region 12 of the buffer layer 10, where the photoresist structure 121 is configured to suppress lateral propagation of light emitted by the light-emitting structure 30.

The buffer layer 10 may be selectively etched to form the photoresist structure 121.

Referring to FIG. 1 and FIG. 2, S140 in which the photoresist structure 121 is prepared in the second region 12 of the buffer layer 10 includes the step described below. A side of the substrate 20 away from the buffer layer 10 is etched to form a groove 21 penetrating the substrate 20, where a vertical projection of the groove 21 on the buffer layer 10 corresponds to the first region 11 and the second region 12; the second region 12 of the buffer layer 10 is selectively etched to form the photoresist structure 121, where the photoresist structure 121 is configured to suppress the lateral propagation of the light emitted by the light-emitting structure 30.

In an embodiment, the photoresist structure 121 includes a first photonic crystal structure, the first photonic crystal structure includes multiple small holes 15 penetrating the buffer layer 10, and the multiple small holes 15 cover the second region 12 and are arranged at intervals; or in other embodiments, the photoresist structure 121 may further include multiple annular grooves 14 penetrating the buffer layer 10, and the multiple annular grooves 14 are disposed at the same center and around the first region 11 at intervals.

Referring to FIG. 3A, FIG. 3A is a top view of a semiconductor structure according to embodiment one of the present disclosure. The second region 12 of the buffer layer 10 forms the photoresist structure 121. The photoresist structure 121 includes a first photonic crystal structure, the first photonic crystal structure includes multiple small holes 15 penetrating the buffer layer 10, and the multiple small holes 15 cover the second region 12 and are arranged at intervals. In the second region 12, an effective refractive index between the small holes 15 and the material of the buffer layer 10 is relatively high, the small holes 15 penetrate the buffer layer 10 in a direction perpendicular to the buffer layer 10, and the multiple small holes 15 are arranged at intervals in a direction parallel to the buffer layer 10. Therefore, in the direction parallel to the buffer layer 10, the first photonic crystal structure, that is, the photoresist structure 121 has a relatively high effective refractive index in the direction parallel to the buffer layer 10, effectively suppressing the lateral guided propagation of light emitted by the light-emitting unit 301 through the second region 12, and thus effectively avoiding light crosstalk. In an optional embodiment, the diameter of the small hole 15 is less than 100 nm. In a direction pointing from the first region 11 to the second region 12, the arrangement density of the small holes 15 in the photoresist structure 121 remains unchanged, gradually decreases or increases so that the photoresist effect is further improved.

In other embodiments, referring to FIG. 3B, FIG. 3B is a top view of another semiconductor structure according to embodiment one of the present disclosure. The photoresist structure 121 includes multiple annular grooves 14 penetrating the buffer layer 10, and the multiple annular grooves 14 are disposed at the same center and around the first region 11 at intervals. Similarly, in the second region 12, an effective refractive index between the annular grooves 14 and the material of the buffer layer 10 is relatively high, the annular grooves 14 penetrate the buffer layer 10 in the direction perpendicular to the buffer layer 10, and the multiple annular grooves 14 are arranged at intervals around each other in the direction parallel to the buffer layer 10. Therefore, in the direction parallel to the buffer layer 10, the photoresist structure 121 has a relatively high effective refractive index in the direction parallel to the buffer layer 10, effectively suppressing the lateral guided propagation of light emitted by the light-emitting unit 301 through the second region 12, and thus effectively avoiding light crosstalk and reducing light loss. In an optional embodiment, the width of a section of the annular groove 14 is less than 100 nm, and the interval between multiple annular grooves 14 is less than 100 nm. The section is the surface perpendicular to the surface of the buffer layer 10. In the direction pointing from the first region 11 to the second region 12, the width of the section of the annular groove 14 in the photoresist structure 121 remains unchanged, gradually decreases or increases, and the section is a surface perpendicular to a surface of the buffer layer 10. The arrangement interval of the annular grooves 14 in the photoresist structure 121 remains unchanged, gradually decreases or increases so that the photoresist effect is further improved.

Referring to FIG. 7, FIG. 7 is a structural diagram of another semiconductor structure according to embodiment two of the present disclosure. S130 in which the light-emitting structure 30 is formed on the side of the buffer layer 10 away from the substrate 20 includes the step described below. A first semiconductor layer 33, a light-emitting layer 34 and a second semiconductor layer 35 are sequentially formed on the side of the buffer layer 10 away from the substrate 20, where the first semiconductor layer 33 is located on a surface of the side of the buffer layer 10 away from the substrate 20. The conduction type of the first semiconductor layer 33 is opposite to the conduction type of the second semiconductor layer 35. The first semiconductor layer 33 is an N-type semiconductor layer, and the second semiconductor layer is a P-type semiconductor layer; or the first semiconductor layer 33 is a P-type semiconductor layer, and the second semiconductor layer is an N-type semiconductor layer.

Referring to FIG. 8, FIG. 8 is a structural diagram of another semiconductor structure according to embodiment two of the present disclosure. S130 in which the light-emitting structure 30 is patterned to form the light-emitting unit 301 includes the step described below. The first semiconductor layer 33, the light-emitting layer 34 and the second semiconductor layer 35 are patterned to form the light-emitting unit 301, where the light-emitting unit 301 is disposed corresponding to the first region 11. After the light-emitting structure 30 is patterned to form the light-emitting unit 301, the light-emitting layer 34 and the second semiconductor layer 35 are further etched to expose at least part of the first semiconductor layer 34 to facilitate subsequent electrode preparation.

The buffer layer 10 may include multiple first regions 11, and the second region 12 surrounds all of the multiple first regions 11. The step in which the light-emitting structure 30 is patterned to form the light-emitting unit 301 includes the step described below. The light-emitting structure 30 is patterned to form multiple light-emitting units 301, where the multiple light-emitting units 301 correspond to the multiple first regions 11 one to one.

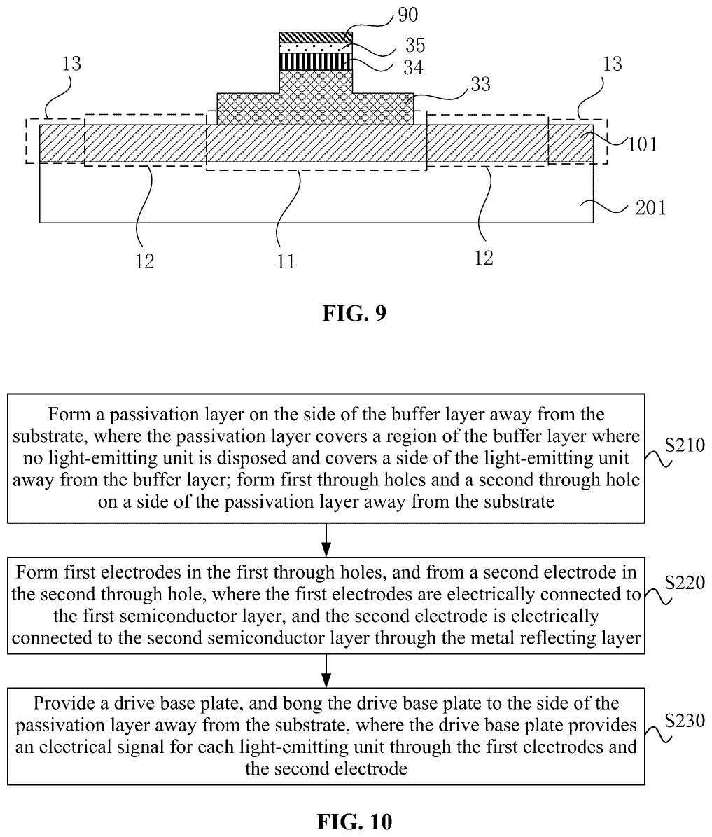

Referring to FIG. 9, FIG. 9 is a structural diagram of another semiconductor structure according to embodiment two of the present disclosure. After the first semiconductor layer 33, the light-emitting layer 34 and the second semiconductor layer 35 are patterned to form the light-emitting unit 301, the step is further included. A metal reflecting layer 90 is formed on a side of the second semiconductor layer 35 away from the light-emitting layer 34.

A metal reflecting layer is formed through the sputtering process.

Referring to FIG. 10 to FIG. 14, FIG. 10 is a flowchart of another preparation method of a semiconductor structure according to embodiment two of the present disclosure, and FIG. 11 to FIG. 14 are diagrams showing another preparation process of a semiconductor structure according to embodiment two of the present disclosure. After the metal reflecting layer 90 is formed on the side of the second semiconductor layer 35 away from the light-emitting layer 34, the step described below is further included.

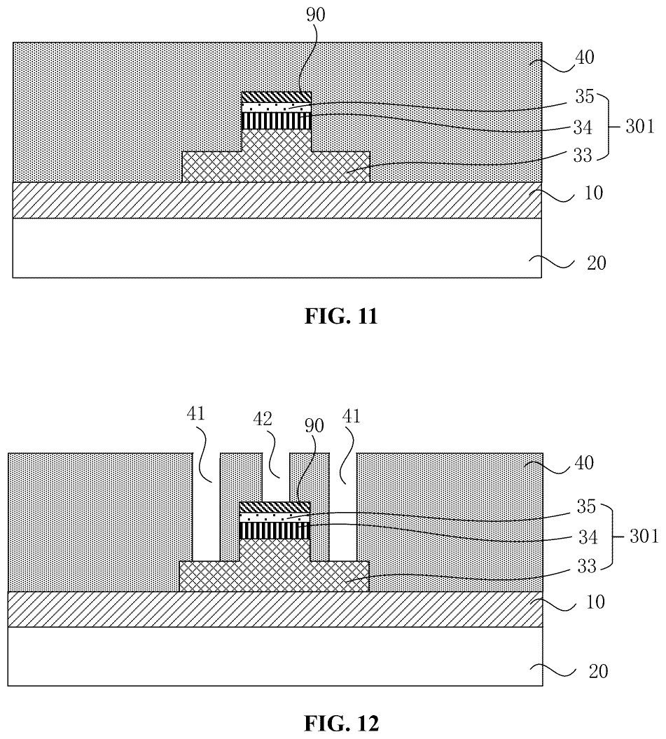

FIG. 11 is a structural diagram of another semiconductor structure according to embodiment two of the present disclosure, and FIG. 12 is a structural diagram of another semiconductor structure according to embodiment two of the present disclosure. Referring to FIG. 11 to FIG. 12, in S210, a passivation layer 40 is formed on the side of the buffer layer 10 away from the substrate 20, where the passivation layer 40 covers a region of the buffer layer 10 where no light-emitting unit 301 is disposed and covers a side of the light-emitting unit 301 away from the buffer layer 10; first through holes 41 and a second through hole 42 are formed on a side of the passivation layer 40 away from the substrate 20.

The first through holes 41 and the second through hole 42 may be formed through etching. The first through holes 41 penetrate to the first semiconductor layer 33, and the second through hole penetrates to the second semiconductor layer 35.

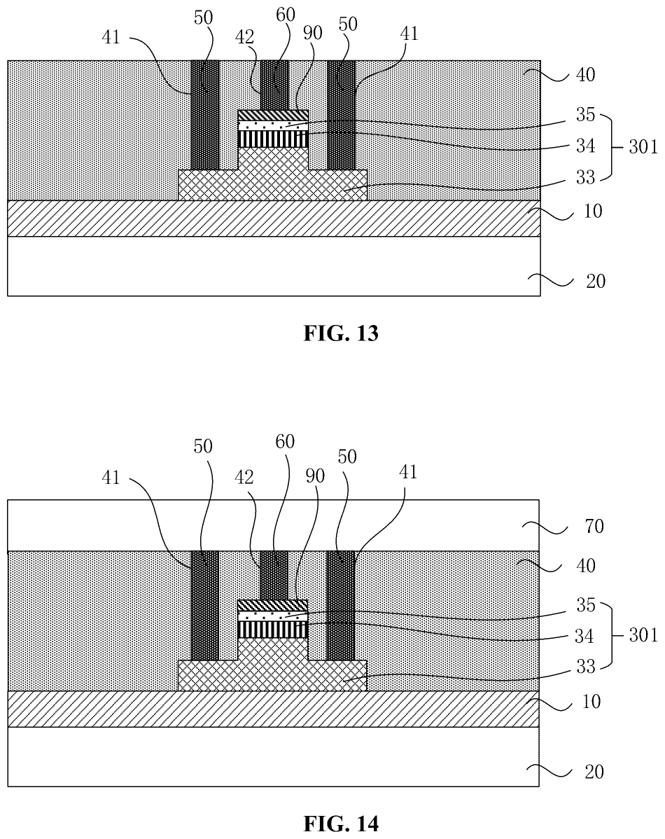

FIG. 13 is a structural diagram of another semiconductor structure according to embodiment two of the present disclosure. Referring to FIG. 13, in S220, first electrodes 50 are formed in the first through holes 41, and a second electrode 60 is formed in the second through hole 42, where the first electrodes 50 are electrically connected to the first semiconductor layer 33, and the second electrode 60 is electrically connected to the second semiconductor layer 35 through the metal reflecting layer 90.

The first through holes 41 and the second through hole 42 are covered with conductive materials to form the first electrodes and the second electrode 60, so that the first electrodes 50 are electrically connected to the first semiconductor layer 33. Due to the conductivity of the metal reflecting layer, the second electrode 60 can be electrically connected to the second semiconductor layer 35 through the metal reflecting layer 90.

FIG. 14 is a structural diagram of another semiconductor structure according to embodiment two of the present disclosure. Referring to FIG. 14, in S230, a drive base plate 70 is provided, and the drive base plate 70 is bonded to the side of the passivation layer 40 away from the substrate 20, where the drive base plate 70 provides an electrical signal for each light-emitting unit 301 through the first electrodes 50 and the second electrode 60.

The drive base plate 70 is configured to drive the light-emitting unit 301 to emit light.

After the second region 12 of the buffer layer 10 is selectively etched to form the photoresist structure 121, the step described below is further includes. An optical fiber 80 is provided, and the optical fiber 80 is coupled to the groove 21 of the substrate 20.

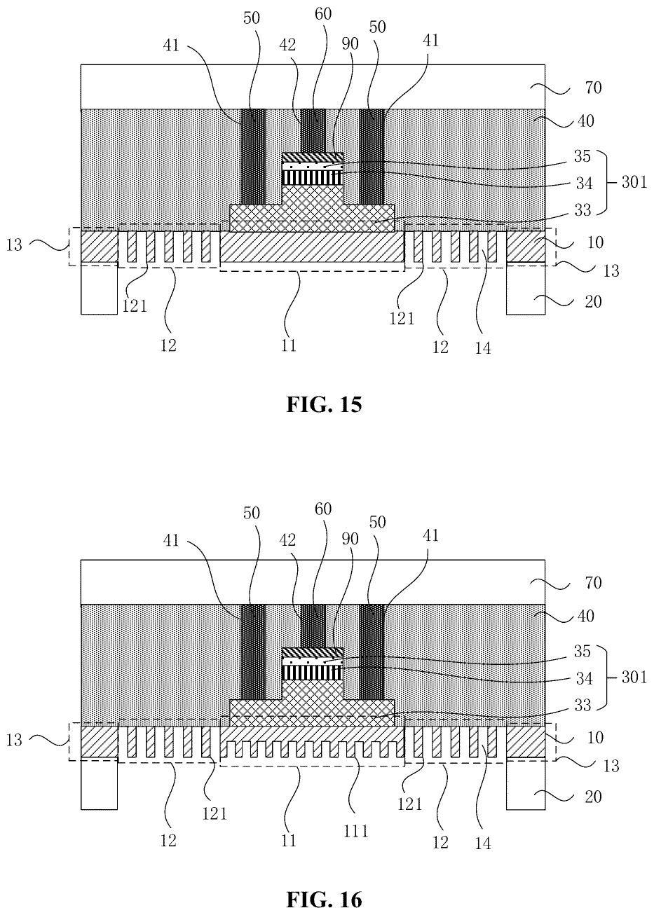

FIG. 15 is a structural diagram of another semiconductor structure according to embodiment two of the present disclosure. Referring to FIG. 15, FIG. 4 shows a structure obtained after the optical fiber 80 is coupled to the groove 21 of the substrate 20, allowing the light emitted by the light-emitting layer 34 to couple to an end of the optical fiber 80 through the first region 11 of the buffer layer 10.

A light-output structure 111 is prepared in the first region 11 of the buffer layer 10 while the photoresist structure 121 is prepared in the second region 12 of the buffer layer 10. The light-output structure 111 is configured to improve the light output efficiency.

Referring to FIG. 16, FIG. 16 is a structural diagram of another semiconductor structure according to embodiment two of the present disclosure. The light-output structure 111 is located in the first region 11, the preparation method of the light-output structure 111 includes selectively etching the first region 11 of the buffer layer 10 to form the light-output structure, during which multiple nano patterns are formed on the side of the buffer layer 10 away from the light-emitting unit 301, where the multiple nano patterns partially penetrate the buffer layer 10 and are arranged in a regular or irregular manner on the side of the buffer layer 10 away from the light-emitting unit 301. The light-output structure 111 greatly improves the light extraction efficiency of the light-emitting unit 301. The light-output structure 111 may be in the form of a wavy line, a serration or may be a nano-patterned structure formed by the combination of multiple nano protrusions and multiple nano grooves. The light-output structure 111 may include a second photonic crystal structure. The second photonic crystal structure includes multiple nano patterns arranged in a regular or irregular manner on the side of the buffer layer 10 away from the light-emitting unit 301.

The embodiment of the present disclosure provides a preparation method of a semiconductor structure on the basis of the preceding embodiment. The preparation method of the semiconductor structure has the same beneficial effects as the semiconductor structure described in any embodiment.

It is to be understood that various forms of the preceding flows may be used with steps reordered, added or deleted. For example, the steps described in the present disclosure may be performed in parallel, in sequence or in a different order as long as the desired result of the technical solutions provided in the present disclosure can be achieved. The execution sequence of these steps is not limited herein.

The scope of the present disclosure is not limited to the preceding embodiments. It is to be understood by those skilled in the art that various modifications, combinations, sub-combinations and substitutions may be made according to design requirements and other factors. Any modification, equivalent substitution, improvement and the like made within the spirit and principle of the present disclosure fall within the scope of the present disclosure.

What is claimed is:

1. A semiconductor structure, comprising:
a substrate;
a buffer layer, wherein the buffer layer is located on the substrate, and the buffer layer comprises a first region and a second region surrounding the first region;
a light-emitting structure located on a side of the buffer layer away from the substrate; and
a photoresist structure, wherein the photoresist structure is formed by selectively etching the second region of the buffer layer, and the photoresist structure is configured to suppress lateral propagation of light emitted by the light-emitting structure;
wherein the light-emitting structure comprises a light-emitting unit, and the light-emitting unit is disposed corresponding to the first region.

2. The semiconductor structure according to claim 1, wherein
the buffer layer comprises a plurality of first regions, and the second region surrounds the plurality of first regions; and
the light-emitting structure comprises a plurality of light-emitting units, and the plurality of light-emitting units are disposed in one-to-one correspondence with the plurality of first regions.

3. The semiconductor structure according to claim 1, wherein
the photoresist structure comprises a first photonic crystal structure, the first photonic crystal structure comprises a plurality of small holes penetrating the buffer layer, and the plurality of small holes cover the second region and are arranged at intervals; or
the photoresist structure comprises a plurality of annular grooves penetrating the buffer layer, and the plurality of annular grooves are disposed at a same center and around the first region at intervals.

4. The semiconductor structure according to claim 1, further comprising:
a light-output structure, wherein the light-output structure is formed by selectively etching the first region of the buffer layer.

5. The semiconductor structure according to claim 4, wherein
the light-output structure comprises a plurality of nano patterns located on a side of the buffer layer away from the light-emitting unit, and the plurality of nano patterns are arranged in a regular or irregular manner on the side of the buffer layer away from the light-emitting unit.

6. The semiconductor structure according to claim 1, wherein
the substrate comprises a groove, the groove penetrates the substrate, and a vertical projection of the groove on the buffer layer corresponds to the first region and the second region.

7. The semiconductor structure according to claim 1, wherein
a maximum size of a vertical projection of the light-emitting unit on the buffer layer is less than or equal to a size of the first region of the buffer layer corresponding to the light-emitting unit.

8. The semiconductor structure according to claim 1, wherein the light-emitting unit comprises a first semiconductor layer, a light-emitting layer and a second semiconductor layer which are sequentially laminated, and the first semiconductor layer is located on a surface of the side of the buffer layer away from the substrate.

9. The semiconductor structure according to claim 8, wherein the light-emitting unit further comprises a metal reflecting layer, and the metal reflecting layer is located on a side of the second semiconductor layer away from the light-emitting layer.

10. The semiconductor structure according to claim 8, further comprising:
a passivation layer, wherein the passivation layer is located on the side of the buffer layer away from the substrate, and the passivation layer covers a region of the buffer layer where no light-emitting unit is disposed, and the passivation layer covers a side of the light-emitting unit away from the buffer layer.

11. The semiconductor structure according to claim 10, wherein
a first through hole and a second through hole which expose the first semiconductor layer and the second semiconductor layer respectively are provided on a side of the passivation layer away from the substrate;
the semiconductor structure further comprises a first electrode and a second electrode which are located within the first through hole and the second through hole respectively; the first electrode is electrically connected to the first semiconductor layer, and the second electrode is electrically connected to the second semiconductor layer through a metal reflecting layer; and
the semiconductor structure further comprises a drive base plate, the drive base plate is bonded to the side of the passivation layer away from the substrate, and the drive base plate provides an electrical signal for the light-emitting unit through the first electrode and the second electrode.

12. The semiconductor structure according to claim 6, further comprising:
an optical fiber, wherein the optical fiber is coupled to the groove of the substrate.

13. A preparation method of a semiconductor structure, comprising:
providing a substrate;
forming a buffer layer on a side of the substrate, wherein the buffer layer comprises a first region and a second region surrounding the first region;
forming a light-emitting structure on a side of the buffer layer away from the substrate and patterning the light-emitting structure to form a light-emitting unit, wherein the light-emitting unit is disposed corresponding to the first region; and
selectively etching the second region of the buffer layer to prepare a photoresist structure, wherein the photoresist structure is configured to suppress lateral propagation of light emitted by the light-emitting structure.

14. The preparation method of a semiconductor structure according to claim 13, wherein selectively etching the second region of the buffer layer to prepare the photoresist structure comprises:
etching a side of the substrate away from the buffer layer to form a groove that penetrates the substrate, wherein a vertical projection of the groove on the buffer layer corresponds to the first region and the second region; and
selectively etching the second region of the buffer layer to form the photoresist structure;
wherein the photoresist structure comprises a first photonic crystal structure, the first photonic crystal structure comprises a plurality of small holes penetrating the buffer layer, and the plurality of small holes cover the second region and are arranged at intervals; or
the photoresist structure comprises a plurality of annular grooves penetrating the buffer layer, and the plurality of annular grooves are disposed at a same center and around the first region at intervals.

15. The preparation method of a semiconductor structure according to claim 13, wherein
the buffer layer comprises a plurality of first regions, and the second region surrounds all of the plurality of first regions; patterning the light-emitting structure to form the light-emitting unit comprises:
patterning the light-emitting structure to form a plurality of light-emitting units, wherein the plurality of light-emitting units correspond to the plurality of first regions one to one.

16. The preparation method of a semiconductor structure according to claim 13, wherein
forming the light-emitting structure on the side of the buffer layer away from the substrate comprises sequentially forming a first semiconductor layer, a light-emitting layer and a second semiconductor layer on the side of the buffer layer away from the substrate; after patterning the light-emitting structure to form the light-emitting unit, the method further comprises:
forming a metal reflecting layer on a side of the second semiconductor layer away from the light-emitting layer.

17. The preparation method of a semiconductor structure according to claim 16, after forming the metal reflecting layer on the side of the second semiconductor layer away from the light-emitting layer, further comprising:
forming a passivation layer on the side of the buffer layer away from the substrate, wherein the passivation layer covers a region of the buffer layer where no light-emitting unit is disposed and covers a side of the light-emitting unit away from the buffer layer; forming a first through hole and a second through hole on a side of the passivation layer away from the substrate to expose the first semiconductor layer and the metal reflecting layer respectively;
forming a first electrode in the first through hole, and forming a second electrode in the second through hole, wherein the first electrode is electrically connected to the first semiconductor layer, and the second electrode is electrically connected to the second semiconductor layer through the metal reflecting layer; and
providing a drive base plate, and bonding the drive base plate to the side of the passivation layer away from the substrate, wherein the drive base plate provides an electrical signal for each of the light-emitting unit through the first electrode and the second electrode.

18. The preparation method of a semiconductor structure according to claim 14, after selectively etching the second region of the buffer layer to form the photoresist structure, further comprising:
providing an optical fiber, and coupling the optical fiber to the groove of the substrate.

19. The preparation method of a semiconductor structure according to claim 13, wherein the first region of the buffer layer is selectively etched to prepare a light-output structure while the second region of the buffer layer is selectively etched to prepare the photoresist structure, wherein the light-output structure is configured to improve light output efficiency of the light-emitting unit.

20. The preparation method of a semiconductor structure according to claim 19, wherein
selectively etching the first region of the buffer layer to prepare the light-output structure comprises:
forming a plurality of nano patterns on a side of the buffer layer away from the light-emitting unit, wherein the plurality of nano patterns are arranged in a regular or irregular manner on the side of the buffer layer away from the light-emitting unit.
